(19) United States
(12) Patent Application Publication
(10) Pub. No.: US 2025/0358948 A1
(43) Pub. Date: Nov. 20, 2025

(54) Pass-through Busbar Module and Immersion Cooling System

(71) Applicant: Tyco Electronics (Shanghai) Co., Ltd., Shanghai (CN)

(72) Inventors: Jie (Roger) Luo, Foshan (CN); William (Wei) Yao, Kunshan (CN); Rong (Summer) Zhang, Shenzhen (CN); Jiaoyong (Mac) Liu, Shanghai (CN)

(73) Assignee: Tyco Electronics (Shanghai) Co., Ltd., Shanghai (CN)

(21) Appl. No.: 19/210,289

(22) Filed: May 16, 2025

(30) Foreign Application Priority Data
May 17, 2024 (CN) 202410620137.0

(51) Int. Cl. H05K 5/06; H01R 25/16; H05K 7/14; H05K 7/20

(52) U.S. Cl. CPC H05K 5/061; H01R 25/162; H05K 5/069; H05K 7/1457; H05K 7/20236; H05K 7/203

(57) ABSTRACT

A pass-through busbar module is configured to pass through a wall of a cooling container of an immersion cooling system in a first direction so as to be mounted onto the wall, and to supply electric power from the outside to an electronic apparatus immersed in a cooling liquid within the cooling container. The pass-through busbar module comprises at least two busbars, which are stacked and partially spaced apart in a thickness direction such that there is a gap between adjacent busbars. The pass-through busbar module further comprises a sealant, which is at least filled in the gap to provide a seal between the busbars.

### CROSS-REFERENCE TO RELATED APPLICATION

This application claims the priority benefit of Chinese Patent Application No. 202410620137.0 filed on May 17, 2024, in the China National Intellectual Property Administration, the whole disclosure of which is incorporated herein by reference.

### FIELD OF THE DISCLOSURE

The present disclosure relates to a field of busbar connection, and more particularly, to a pass-through busbar module capable of providing a sealing function and an immersion cooling system including the pass-through busbar module.

### BACKGROUND

With the gradual development of high-density business applications such as artificial intelligence, virtual reality, smart cities or the like, the computational workload and complexity that a data center needs to cope with are rapidly increasing. The data center is a strategic resource and new infrastructure that support the development of modern economy and society, and which is used for collecting, storing, processing, and distributing large amounts of data. There are a large number of heat generating apparatuses such as computing apparatuses and information communication apparatuses in the data center, and their operating temperature is an important factor that seriously affects their stable performance. With the continuous increase of the amount of data processing, the heat dissipation of the data center is facing more and more serious challenges.

The current cooling solutions may be divided into two categories: a gas cooling (air cooling) and a liquid cooling. The liquid cooling technology improves cooling efficiency by liquid circulation heat exchange, which may significantly reduce the total energy consumption and carbon dioxide emissions of the data center, which meets the requirements of low carbon development. The liquid cooling of the data center can be divided into an immersion type, a cold-plate type, and others. Immersion liquid cooling is typical direct contact liquid cooling, wherein the heat generating apparatus is immersed in a cooling liquid within a cooling container, and the heat generated by the operation of the apparatus is carried away by flow and circulation of the cooling liquid. Since the direct contact between the heat generating apparatus and the cooling liquid in the immersion liquid cooling, the heat dissipation efficiency is higher and the noise is lower, and the problem of higher heat density may be solved.

The immersion liquid cooling may include a single-phase liquid cooling and a two-phase liquid cooling. The single-phase liquid cooling means that the cooling liquid does not undergo phase transformation and is maintained in a liquid state during circulating and heat dissipation. The two-phase liquid cooling means that the cooling liquid undergoes phase transformation during circulating and heat dissipation, that is, the heat from the heat generating apparatus causes the cooling liquid to boil, so as to produce steam, which rises and condenses at a heat exchanger, thereby exponentially increasing the heat transfer efficiency. In the liquid cooling heat dissipation technology, electric power is usually supply from a power supply rack located outside of a cooling container to an apparatus immersed in the cooling liquid within the cooling container by a busbar that passes through a wall of the cooling container. A pressure in the cooling container is usually higher than that that in its surrounding environment, thus, it is necessary to have a good seal between the busbar and the wall of the cooling container to avoid the leakage of the cooling liquid. However, a conventional busbar or busbar assembly itself cannot provide this sealing function.

### SUMMARY

According to an embodiment of the present disclosure, a pass-through busbar module is configured to pass through a wall of a cooling container of an immersion cooling system in a first direction so as to be mounted onto the wall, and to supply electric power from the outside to an electronic apparatus immersed in a cooling liquid within the cooling container. The pass-through busbar module comprises at least two busbars, which are stacked and partially spaced apart in a thickness direction such that there is a gap between adjacent busbars. The pass-through busbar module further comprises a sealant, which is at least filled in the gap to provide a seal between the busbars.

### BRIEF DESCRIPTION OF THE DRAWINGS

The accompanying drawings incorporated therein and forming a part of the specification illustrate the present disclosure and, and together with the description, further serve to explain the principles of the disclosure and to enable those skilled in the relevant art to manufacture and use the embodiments described herein.

FIG. 1 is a block diagram schematically showing a configuration of an immersion cooling system according to an exemplary embodiment of the present disclosure;

FIG. 2 is a perspective view schematically showing a structure of a pass-through busbar module according to an exemplary embodiment of the present disclosure;

FIG. 3 is a top view schematically showing a structure of a pass-through busbar module according to an exemplary embodiment of the present disclosure;

FIG. 4 is a side view schematically showing a structure of a pass-through busbar module according to an exemplary embodiment of the present disclosure;

FIG. 5 is a perspective view schematically showing a structure of a pass-through busbar module according to an exemplary embodiment of the present disclosure, with an installation panel removed;

FIG. 6 is a perspective view schematically showing a structure of an installation panel of a pass-through busbar module according to an exemplary embodiment of the present disclosure;

FIG. 7 is a cross-sectional view of the pass-through busbar module, taken along a line A-A′ in FIG. 3, according to an exemplary embodiment of the present disclosure; and

FIG. 8 is a partially enlarged view schematically showing a structure of a portion of the pass-through busbar module shown in the dashed circle in FIG. 7, according to an exemplary embodiment of the present disclosure.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION OF THE EMBODIMENTS

Embodiments of the present disclosure will be described hereinafter in detail taken in conjunction with the accompanying drawings. In the description, the same or similar parts are indicated by the same or similar reference numerals. The description of each of embodiments of the present disclosure hereinafter with reference to the accompanying drawings is intended to explain the general inventive concept of the present disclosure and should not be construed as a limitation on the present disclosure.

In addition, in the following detailed description, for the sake of explanation, numerous specific details are set forth in order to provide a thorough understanding of the disclosed embodiments. It will be apparent, however, that one or more embodiments may also be practiced without these specific details. In other instances, well-known structures and devices are illustrated schematically in order to simplify the drawing.

In the following detailed description, the directional term, such as “front”, “back”, “up”, “down”, “top”, “bottom”, “left”, “right”, “upper” and “lower”, “inside”, “outside”, etc., may be defined in accordance with the drawings, but the shape and the location of the component is not limited by the term and can be adjusted according to actual applications.

In addition, the term used herein is for the purpose of describing example embodiments only and is not intended to limit and or restrict the present disclosure. The singular forms “a,” “an” and “the” are intended to include the plural forms as well, unless the context clearly indicates otherwise. In the present disclosure, the terms “including,” “comprising,” “having,” and the like are used to specify features, numbers, steps, operations, elements, components, or combinations thereof, but do not preclude the presence or addition of one or more of the features, numbers, steps, operations, elements, components, or combinations thereof.

Although the terms “first,” “second,” etc., may be used herein to describe various elements, but these elements are not limited by these terms. These terms are only used to distinguish one element from another element. For example, without departing from the scope of the present disclosure, a first element may be termed as a second element, and a second element may be termed as a first element. The term of “and/or” includes a plurality of combinations of relevant items or any one item among a plurality of relevant items.

FIG. 1 shows a main configuration of an exemplary immersion liquid cooling system, which may be used to cool various apparatuses will be arranged in a data center, a computing center, a computer room, a vehicle, a power grid system, a radar system or the like and which will generate heat during operation; for example, the apparatuses include an electronic apparatus such as a server, a storage apparatus, a network apparatus, a computing apparatus, a power supply apparatus, etc.

The immersion liquid cooling system may include a single-phase liquid cooling system and a two-phase liquid cooling system. FIG. 1 schematically shows a configuration of a two-phase immersion liquid cooling system, which is used for cooling an electronic apparatus 12, and which mainly includes a cooling container 10, a cooling liquid 11 contained in the cooling container 10, and a heat exchanger 13 arranged in the cooling container 10. The heat exchanger 13 may include a condenser, and the electronic apparatus 12 is immersed in the cooling liquid 11. The heat from the electronic apparatus 12 causes the cooling liquid 11 to boil so as to produce steam, which rises and condenses at the heat exchanger 13, and the heat exchanger 13 transfers the heat to the outside, for example, via a heat exchange medium (e.g., water).

In the immersion liquid cooling system, a pass-through busbar module 100 is further provided. The pass-through busbar module 100 may be configured to pass through a wall of the cooling container 10 in a first direction Y so as to be mounted onto the wall, for example, the pass-through busbar module 100 may be partially inserted into and pass through a penetrating hole (not shown) formed in the wall of the cooling container 10 to supply electric power from the outside, for example, from an external power supply rack 20, to the electronic apparatus 12 immersed in the cooling liquid 11. A pressure in the cooling container 10 is usually higher than that in its surrounding environment, thus, it is necessary to have a good seal between the pass-through busbar module 100 and the wall of the cooling container 10 to avoid the leakage of the cooling liquid. However, in a conventional pass-through busbar module, a plurality of busbars are stacked together without gap, in which an insulating material layer, such as a polyester film or a Mylar sheet, is sandwiched between the busbars when the busbars are stacked, but a bubble is inevitably generated in the insulating material layer during the stacking process, resulting in a weakened seal between the busbars.

However, in the exemplary embodiments of the disclosure, as described below, the pass-through busbar module 100 itself is provided with a sealant capable of sealing a gap between the pass-through busbar module 100 and the wall of the cooling container 10 to provide a good seal therebetween. It will be understood that the pass-through busbar module and the immersion liquid cooling system provided by the present disclosure may also be applied to the single-phase cooling system or other liquid cooling systems.

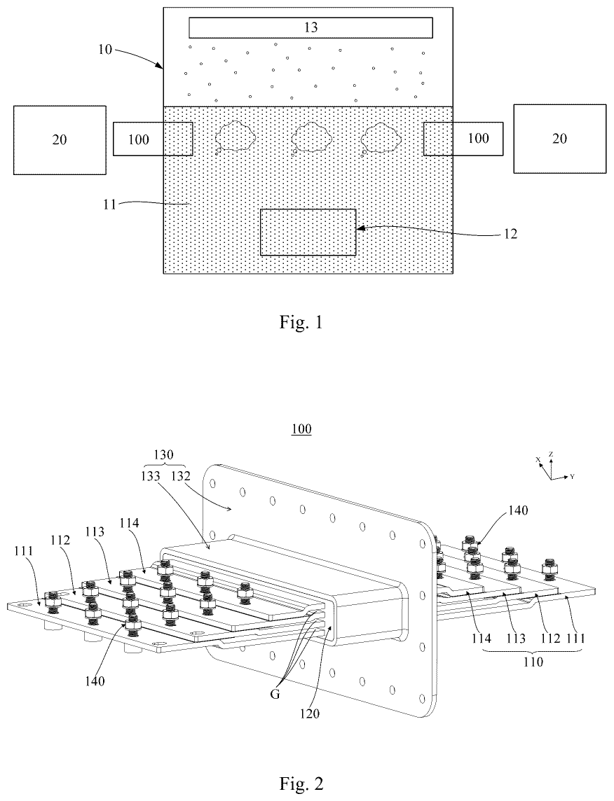

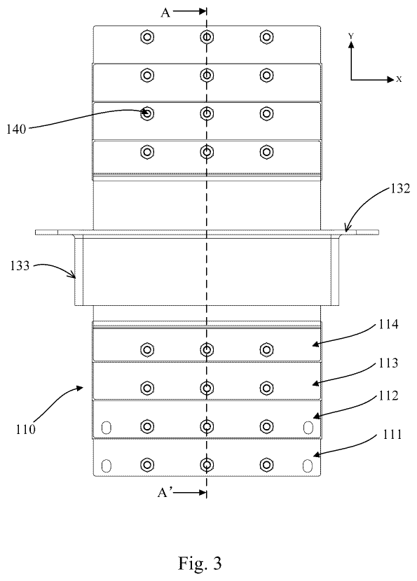

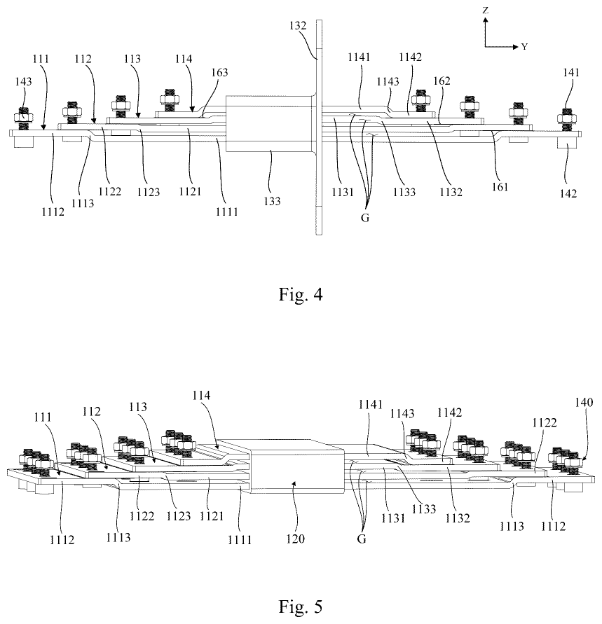

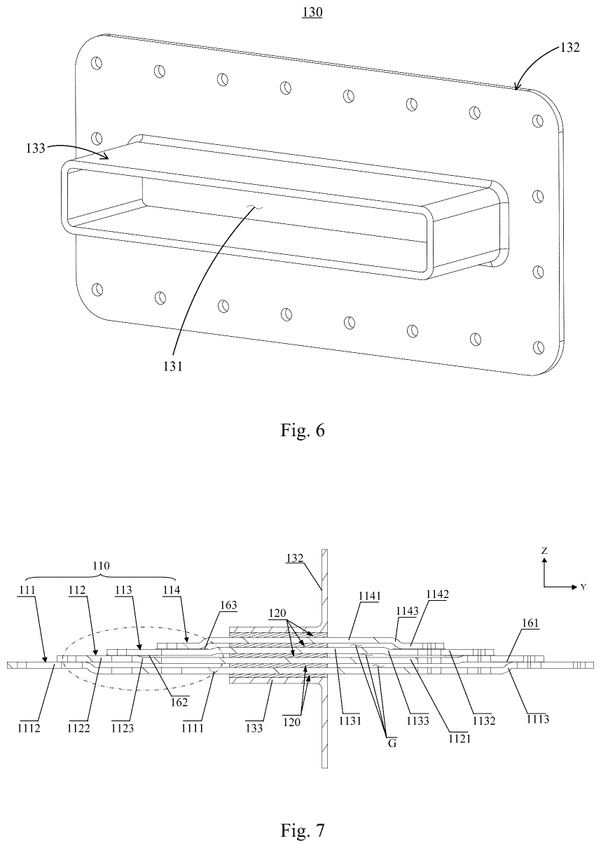

FIGS. 2-8 schematically shows a structure of a pass-through busbar module according to exemplary embodiments of the present disclosure. The pass-through busbar module 100 may be a stacked structure, including at least two busbars 110 for transmitting electric power. The busbar is made of a conductive material such as copper, aluminum, or the like, or may have a conductive coating. The busbar 110 may be electrically and mechanically connected to an external power supply (e.g., the power supply rack 20) and the electronic apparatus 12 (or its electrical connector) by a fastening assembly 140. In the exemplary embodiments of the present disclosure, the individual busbars 110 are (at least partially) stacked or overlapped with each other in its thickness direction Z (which is, for example, perpendicular to the first direction Y), and at least partially spaced apart from each other, so that a gap G is formed or defined between adjacent busbars 110. As an example, each busbar 110 may have a roughly plate or sheet shape as a whole, with a length extending in the first direction Y and a width extending in a second direction X perpendicular to the first direction Y. The first direction Y is parallel to a length direction of the busbar or may also be referred to as the length direction of the busbar herein. The individual busbars 110 are at least partially stacked or overlapped with each other in a face-to-face manner in the thickness direction Z.

As shown in the figures, the pass-through busbar module 100 further includes a sealant 120, which may be at least filled in the gap G to provide a seal between the individual busbars 110, so that the cooling liquid 11 within the cooling container 10 cannot leak out through the gap between the busbars 110 after mounting the pass-through busbar module 100 onto the wall of the cooling container 10. Thereby, compared to the conventional pass-through busbar module stacked without gap, the pass-through busbar module according to the exemplary embodiments of the present disclosure has the gap between the adjacent busbars 110, which facilitates the filling of the sealant 120 or sealing material in the gap, thereby providing the good seal between the individual busbars. As an example, the sealant 120 may include an adhesive, such as an epoxy resin glue, that bonds the adjacent busbars 110 together.

In the exemplary embodiments of the present disclosure, as shown in FIGS. 2, 5 and 7, the sealant 120 is circumferentially wrapped around an outside of the individual busbars 110, so that in a cross-section of the pass-through busbar module 100 being perpendicular to the first direction Y, the sealant 120 is circumferentially wrapped around each busbar 110 to form a sealing barrier for preventing the leakage of the cooling liquid. The sealant 120 is at least filled in the gap G at least at a position where the pass-through busbar module 100 passes through the wall of the cooling container 10, and filled in a gap between the pass-through busbar module 100 and the wall of the cooling container 10 at the penetrating hole, i.e., seals the penetrating hole (not shown) formed in the wall, so that the cooling liquid within the cooling container 10 will not leak out through the penetrating hole after the pass-through busbar module 100 is partially inserted into and passes through the penetrating hole.

The pass-through busbar module 100 may include two or more stacked busbars. In the illustrated embodiments, the pass-through busbar module 100 includes four stacked busbars in the thickness direction Z, but the present disclosure is not limited to this. As shown in FIGS. 2-5, 7 and 8, the at least two busbars 110 of the pass-through busbar module 100 include a first busbar 111, a second busbar 112, a third busbar 113 and a fourth busbar 114 stacked in sequence in the thickness direction Z, gaps G are formed or defined between the first busbar 111 and the second busbar 112, between the second busbar 112 and the third busbar 113, and between the third busbar 113 and the fourth busbar 114, respectively, so that the sealant 120 are partially filled in the gaps G.

In the exemplary embodiments of the present disclosure, each busbar (110; 111, 112, 113, 114) includes a middle section and two end sections located at opposite sides of the middle section in a length direction, and in a state that the pass-through busbar module 100 passes through the wall (its penetrating hole) of the cooling container 10 to be mounted onto the wall, the middle section of each busbar (110; 111, 112, 113, 114) is partially inserted into and passes through the wall (its penetrating hole) of the cooling container 10, the opposite end sections of each busbar 110 are positioned inside and outside of the cooling container 10, respectively, and the fastening assembly 140 is provided in the end sections. As an example, as shown in FIGS. 2, 4, and 5, the fastening assembly 140 may include a bolt 141 for inserting into a mounting hole (not shown) formed in the end section(s), a fixing cap 142 for fixing the bolt 141 to the busbar (or its end section), and a nut 143 connected to the bolt 141. A connection component (not shown) that is electrically connected to the external power supply (e.g., the power supply rack 20) and the electronic apparatus 12 may be pressed against the busbar 110 (or its end section) by the nut 143 to establish a reliable electrical connection between the connection component and the busbar. In some examples, some fixing caps 142 may be positioned between adjacent busbars in the thickness direction Z and therefore electrically isolated from the busbars.

In the illustrated embodiment, the middle sections of the individual busbars (110; 111, 112, 113, 114) are at least partially overlapped with each other in the thickness direction, for example, centers of the middle sections of the individual busbars are aligned in the thickness direction, and there is the gap G at least between the middle sections of the adjacent busbars. The sealant 120 is filled between at least portions of the middle sections of the adjacent busbars, and the filled sealant 120 at least covers or exceeds a width of the middle section.

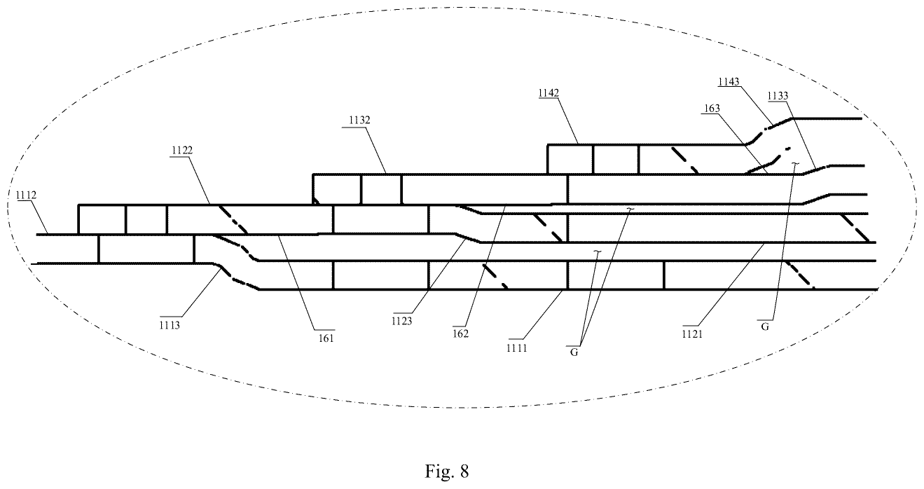

In some embodiments, the corresponding end sections of the adjacent busbars (110; 111, 112, 113, 114) may be at least partially abutted or pressed against each other (e.g., face-to-face), so that there is no gap between the corresponding end sections of the adjacent busbars to provide a further seal. As shown in FIG. 8, an insulting material layer (161, 162, 163) is provided between the corresponding end sections of the adjacent busbars, so that the adjacent busbars are electrically isolated or insulated from each other by the insulting material layer and the gap G, so as not to interfere with power transmission of the individual busbars. The insulating material layer may be formed (e.g., coated) on one of two surfaces of the corresponding end sections of the adjacent busbars facing each other, and provided at least between the overlapped portions of the end sections in the thickness direction Z. As an example, the insulating material layer may be made of a material such as PET, epoxy resin or the like, and may have a thickness of 0.1 mm to 0.5 mm.

The gap into which the sealant is to be filed may be formed or defined between the adjacent busbars by means of a variety of manners. In the illustrated embodiments, as shown in FIGS. 2, 4, 5 and 8, each busbar (110; 111, 112, 113, 114) may further include a transition section, which extends from the middle section to the end section so that the middle section is recessed relative to the end section in the thickness direction Z, thus each busbar (110; 111, 112, 113, 114) has a recess defining the gap G. For example, one surface of each busbar is recessed relative to the end sections at the middle section, in other words, surfaces of the middle section and the end sections of each busbar facing adjacent busbar are misaligned, or are positioned within different planes perpendicular to the thickness direction Z. In the illustrated embodiments, the middle section and/or the end sections may have a flat contour, so that each busbar presents a substantially flat contour with a recess as a whole, but the present disclosure is not limited to this. In other embodiments not shown, each busbar may have a plate shape or other shape, and a spacer (not shown) may be provided between the adjacent busbars, the spacer having a desired dimension in the thickness direction Z to define the gap, which is adapted to be filled with the sealant between the adjacent busbars. It will be understood that the thicknesses of respective busbars may be the same as or different from each other.

In the illustrated embodiments, the transition sections of the busbars (110; 111, 112, 113, 114) extend obliquely relative to the thickness direction Z and the first direction Y, and an inclination direction and/or angle of the corresponding transition sections of the adjacent arranged busbars may be different. For example, in the case that the recesses of the adjacent arranged busbars face the same direction, their corresponding transition sections have different inclination directions and/or angles. However, in the case that the recesses of the adjacent arranged busbars face two opposite directions, the inclination directions and/or angles of their corresponding transition sections may be the same as or different from each other. In other embodiments not shown, the transition sections of the busbars may extend substantially in the thickness direction.

In the embodiments shown in FIGS. 2-5 and 7-8, lengths of the first busbar 111, the second busbar 112, the third busbar 113, and the fourth busbar 114 are sequentially decreased, and the busbars may be centrally aligned in the thickness direction when stacked, so that the overall pass-through busbar module presents a stepped shape with a central protrusion, however, the present disclosure is not limited to this. In other embodiments, the lengths and/or widths of the individual busbars may be the same as or different from each other, depending on specific application requirements.

Referring to FIGS. 2-5 and 7-8, the first busbar 111 includes a first middle section 1111, two first end sections 1112 located at opposite sides of the first middle section 1111 in the length direction Y, and first transition sections 1113 each extending from the first middle section 1111 to the corresponding first end section 1112. The first middle section 1111 is recessed relative to the first end sections 1112 in the thickness direction Z so that a surface of the first middle section 1111 and surfaces of the first end sections 1112 are positioned within different planes (e.g., which are perpendicular to the thickness direction Z).

As shown in FIGS. 2-5 and 7-8, the second busbar 112 includes a second middle section 1121, two second end sections 1122 located at opposite sides of the second middle section 1121 in the length direction Y, and second transition sections 1123 each extending from the second middle section 1121 to the corresponding second end section 1122; the second middle section 1121 is recessed relative to the second end sections 1122 in the thickness direction Z so that a surface of the second middle section 1121 and surfaces of the second end sections 1122 are positioned within different planes (e.g., which are perpendicular to the thickness direction Z). The second middle section 1121 is spaced apart from the first middle section 1111 of the first busbar 111 in the thickness direction Z; as an example, the second end section 1123 is abutted against the corresponding first end section 1113 of the first busbar 111, and a first insulating material layer 161 is provided between the second end section 1122 and the first end section 1112 to electrically isolate or insulate the second busbar 112 from the first busbar 111. The sealant 120 is filled in at least a portion of the gap G between the first middle section 1111 and the second middle section 1121 in the length direction or the first direction Y.

Still referring to FIGS. 2-5 and 7-8, the third busbar 113 includes a third middle section 1131, two third end sections 1132 located at opposite sides of the third middle section 1131 in the length direction, and third transition sections 1133 each extending from the third middle section 1131 to the corresponding third end section 1132; the third middle section 1131 is recessed relative to the third end sections 1132 in the thickness direction Z so that a surface of the third middle section 1131 and surfaces of the third end sections 1132 are located within different planes (e.g., which are perpendicular to the thickness direction Z). The third middle section 1131 is spaced apart from the second middle section in the thickness direction Z; as an example, the third end section 1132 is abutted against the corresponding second end section 1132 of the second busbar 112, and a second insulating material layer 162 is provided between the third end section 1132 and the second end section 1122 to electrically isolate or insulate the third busbar 113 from the second busbar 112. The sealant 120 is filled in at least a portion of the gap G between the second middle section 1121 and the third middle section 1131 in the length direction or the first direction Y.

As shown in FIGS. 2-5 and 7-8, the fourth busbar 114 includes a fourth middle section 1141, two fourth end sections 1142 located at opposite sides of the fourth middle section 1141 in the length direction, and fourth transition sections 1143 each extending from the fourth middle section 1141 to the corresponding fourth end section 1142, the fourth middle section 1141 being recessed relative to the fourth end section 1142 in the thickness direction Z so that a surface of the fourth middle section 1141 and surfaces of the fourth end sections 1142 are located within different planes (e.g., which are perpendicular to the thickness direction Z). The fourth middle section 1141 is spaced apart from the third middle section 1131 of the third busbar 113 in the thickness direction Z; the fourth end section 1142 is abutted against the corresponding third end section 1132 of the third busbar 113, and a third insulating material layer 163 is provided between the fourth end section 1142 and the third end section 1132 to electrically isolate or insulate the fourth busbar 114 from the third busbar 113 The sealant 120 is filled in at least a portion of the gap G between the third middle section 1131 and the fourth middle section 1141 in the length direction or the first direction Y.

In the illustrated embodiments, in the state that the first busbar 111, the second busbar 112, the third busbar 113 and the fourth busbar 114 are stacked, the first middle section 1111 and the second middle section 1121 are recessed in the same direction, while the third middle section 1131 and the fourth middle section 1141 are recessed in another direction opposite to the direction in which the first middle section 1111 and the second middle section 1121 are recessed, so that the recesses of the first busbar 111 and the second busbar 112 face the same direction, the recesses of the third busbar 113 and the fourth busbar 114 face another opposite direction, and the recess of the second busbar 112 faces the recess of the third busbar 113.

As described above, the inclination direction and/or angle of the corresponding transition sections of the individual busbars may be the same as or different from each other based on the difference of the arrangements, orientations, and/or thicknesses of the individual busbars. In the embodiments shown in FIGS. 2-5 and 7-8, the first busbar 111, the second busbar 112, the third busbar 113 and the fourth busbar 114 may have approximately the same thickness. The inclination angle of the second transition section 1123 relative to the thickness direction Z is larger than that of the first transition section 1113 relative to the thickness direction, or a size of the second transition section 1123 in the thickness direction Z is smaller than that of the first transition section 1113 in the thickness direction; and the inclination angle of the third transition section 1133 relative to the thickness direction Z is larger than that of the fourth transition section 1143 relative to the thickness direction Z, or a size of the third transition section 1133 in the thickness direction Z is smaller than that of the fourth transition section 1143 in the thickness direction Z. The embodiments of the present application are not limited to the illustrated inclination direction and/or angle.

In some exemplary embodiments of the present application, as shown in FIGS. 2-7, the pass-through busbar module may further include an installation panel 130 formed with a through-hole 131, the pass-through busbar module or the stacked busbars (110; 111, 112, 113, 114) thereof is adapted to be inserted into and pass through the through-hole 131 to be partially positioned in the cooling container 10, and the sealant 120 is further filled in a gap between an inner wall of the installation panel 130 defining the through-hole 131 (that is, an inner wall surface of the through-hole 131) and the pass-through busbar module or the busbars thereof to provide a seal between the pass-through busbar module and the inner wall of the installation panel 130 defining the through-hole 131. Illustratively, the installation panel 130 may be formed as at least a portion of the wall of the cooling container 10, thus the through-hole 131 forms or is the aforementioned penetrating hole. As an alternative, the installation panel 130 is adapted to be detachably installed onto the wall of the cooling container 10. As an example, the installation panel may be made of stainless steel or other suitable materials, and its thickness may be from 0.5 cm to 2 cm.

In the illustrated embodiments, the installation panel 130 includes a plate-shaped panel body 132 and a cylindrical structure 133 (e.g., integrally) extending from the panel body 132 in the first direction Y, the cylindrical structure 133 defining or being formed with the through-hole 131. The sealant 120 is further filled between an inner wall of the cylindrical structure 133 and the pass-through busbar module or the busbars (110; 111, 112, 113, 114) thereof to seal the gap between the cylindrical structure 133 and the pass-through busbar module or the busbars thereof. For example, as shown in the figures, the sealant 120 is filled between an outer surface of the first busbar 111 and the inner wall of the cylindrical structure 133, between an outer surface of the fourth busbar 114 and the inner wall of the cylindrical structure 133, and between a side surface of the pass-through busbar module or the busbars (110; 111, 112, 113, 114) thereof and the inner wall of the cylindrical structure 133. As an example, the sealant may be fully positioned within the cylindrical structure, but the present disclosure is not limited to this. Depending on practical applications, for example, based on sealing or installation requirements, the cylindrical structure may extend from the panel body to a desired length, for example, 5 cm to 20 cm, and the cylindrical structure may be adapted to be positioned inside or outside of the cooling container.

Although the example embodiments of the present disclosure have been shown and described, it would be appreciated by those skilled in the art that various changes (e.g., different combinations of embodiments or features) may be made to these embodiments without departing from the principles and spirit of the disclosure, the scope of which is defined by the appended claims and their equivalents. Additionally, it is to be noted that the terms “comprising,” “including,” “having” used therein do not exclude other components or steps. Furthermore, any reference numerals in the claims shall not be construed as limiting the scope of the disclosure.

What is claimed is:

1. A pass-through busbar module configured to pass through a wall of a cooling container of an immersion cooling system in a first direction so as to be mounted onto the wall, and to supply electric power from the outside to an electronic apparatus immersed in a cooling liquid within the cooling container,
the pass-through busbar module comprises at least two busbars, which are stacked and partially spaced apart in a thickness direction such that there is a gap between adjacent busbars, and
the pass-through busbar module further comprises a sealant, which is at least filled in the gap to provide a seal between the busbars.

2. The pass-through busbar module according to claim 1, wherein, the sealant is circumferentially wrapped around an outside of the at least two busbars, so that the sealant is circumferentially wrapped around each busbar in a cross-section of the pass-through busbar module perpendicular to the first direction.

3. The pass-through busbar module according to claim 2, wherein, the gap is filled with the sealant at least at a position where the pass-through busbar module passes through the wall.

4. The pass-through busbar module according to claim 2, wherein, the sealant comprises an adhesive that bonds the adjacent busbars together.

5. The pass-through busbar module according to claim 2, wherein each busbar has a roughly plate shape and comprises a middle section and two end sections located at opposite sides of the middle section in a length direction which is parallel to the first direction, and the two end sections of each busbar are configured to be positioned outside and an inside of the cooling container respectively in a state that the pass-through busbar module is mounted onto the wall.

6. The pass-through busbar module according to claim 5, wherein:
the gap is formed between the middle sections of the adjacent busbars,
the middle sections of the busbars are at least partially overlapped in the thickness direction, and
the sealant is filled between at least portions of adjacent middle sections.

7. The pass-through busbar module according to claim 6, wherein the corresponding end sections of the adjacent busbars are at least partially abutted against each other, so that there is no gap between the corresponding end sections of the adjacent busbars.

8. The pass-through busbar module according to claim 7, wherein an insulating material layer is provided between the corresponding end sections of the adjacent busbars, so that the adjacent busbars are electrically isolated from each other by the insulating material layer and the gap.

9. The pass-through busbar module according to claim 5, wherein each busbar further comprises transition sections, which each extend from the middle section to the corresponding end section, so that the middle section is recessed relative to the end sections in the thickness direction, thereby each busbar has a recess defining the gap.

10. The pass-through busbar module according to claim 9, wherein surfaces of the middle section and the end section of each busbar facing an adjacent busbar are located within different planes perpendicular to the thickness direction.

11. The pass-through busbar module according to claim 9, wherein the transition section extends in the thickness direction, or the transition section extends obliquely with respect to the thickness direction and the first direction.

12. The pass-through busbar module according to claim 9, wherein each of the middle section and the end section has a flat contour.

13. The pass-through busbar module according to claim 10, wherein:
the at least two busbars comprise a first busbar, a second busbar, a third busbar, and a fourth busbar stacked in sequence in the thickness direction,
the first busbar comprises a first middle section, two first end sections located at opposite sides of the first middle section in a length direction, and first transition sections each extending from the first middle section to the corresponding first end section,
the second busbar comprises a second middle section, two second end sections located at opposite sides of the second middle section in a length direction, and second transition sections each extending from the second middle section to the corresponding second end sections, the second middle section being spaced apart from the first middle section in the thickness direction, and the second end section being abutted against the corresponding first end section,
the third busbar comprises a third middle section, two third end sections located at opposite sides of the third middle section in a length direction, and third transition sections each extending from the third middle section to the third end sections, the third middle section being spaced apart from the second middle section in the thickness direction, and the third end section being abutted against the corresponding second end section, and
the fourth busbar comprises a fourth middle section, two fourth end sections located at opposite sides of the fourth middle section in a length direction, and fourth transition sections each extending from the fourth middle section to the corresponding fourth end section, the fourth middle section being spaced apart from the third middle section in the thickness direction, and the fourth end section being abutted against the corresponding third end section.

14. The pass-through busbar module according to claim 13, wherein in a state that the first busbar, the second busbar, the third busbar and the fourth busbar are stacked, the first middle section and the second middle section are recessed in the same direction, and the third middle section and the fourth middle section are recessed in another direction opposite to the direction in which the first middle section and the second middle section are recessed.

15. The pass-through busbar module according to claim 14, wherein:
an inclination angle of the second transition section relative to the thickness direction is greater than that of the first transition section relative to the thickness direction, and
an inclination angle of the third transition section relative to the thickness direction is greater than that of the fourth transition section relative to the thickness direction.

16. The pass-through busbar module according to claim 13, wherein the pass-through busbar module further comprises:
a first insulating material layer provided at least between the first end section and the corresponding second end section to electrically isolate the second busbar from the first busbar;
a second insulating material layer provided at least between the second end section and the corresponding third end section to electrically isolate the third busbar from the second busbar; and
a third insulating material layer provided at least between the third end section and the corresponding fourth end section to electrically isolate the fourth busbar from the third busbar.

17. The pass-through busbar module according to claim 1, wherein:
the pass-through busbar module further comprises an installation panel formed with a through-hole, the at least two busbars being adapted to pass through the through-hole to be partially positioned within the cooling container, and
the sealant is further filled in a gap between an inner wall of the installation panel defining the through-hole and the at least two busbars.

18. The pass-through busbar module according to claim 17, wherein the installation panel is formed as at least a portion of the wall of the cooling container, or the installation panel is adapted to be detachably installed onto the wall of the cooling container.

19. The pass-through busbar module according to claim 17, wherein:
the installation panel comprises a plate-shaped panel body and a cylindrical structure extending from the panel body in the first direction, the cylindrical structure defining the through-hole, and
the sealant is filled between an inner wall of the cylindrical structure and the at least two busbars to seal a gap between the cylindrical structure and the at least two busbars.

20. An immersion cooling system comprising:
a cooling container, a wall of which is formed with a penetrating hole;
a cooling liquid contained in the cooling container, such that an electronic apparatus is adapted to be immersed in the cooling liquid; and
the pass-through busbar module according to claim 1, the pass-through busbar module being partially inserted into and passing through the penetrating hole and configured to supply electric power from the outside to the electronic apparatus immersed in the cooling liquid, wherein a gap between the pass-through busbar module and the wall is sealed by the sealant.
